(19) United States
(12) Patent Application Publication
(10) Pub. No.: US 2021/0039182 A1
(43) Pub. Date: Feb. 11, 2021

(54) Method for Producing a Structural Unit and Method for Connecting a Component to such a Structural Unit

(71) Applicant: Siemens Aktiengesellschaft, München (DE)

(72) Inventors: Christian Schellenberg, Potsdam (DE); Jörg Strogies, Berlin (DE)

(73) Assignee: Siemens Aktiengesellschaft, München (DE)

(21) Appl. No.: 16/967,822

(22) PCT Filed: Feb. 7, 2019
(86) PCT No.: PCT/EP2019/053030

§ 371 Date: Aug. 6, 2020

(30) Foreign Application Priority Data
Feb. 8, 2018 (DE) 10 2018 201 974.6

(51) Int. Cl. B23K 1/00; B23K 1/20; H05K 3/30

(52) U.S. Cl. CPC B23K 1/0016; B23K 2101/42; H05K 3/303; B23K 1/20

(57) ABSTRACT

Various embodiments include a method for producing a structural unit to be soldered to a component by diffusion soldering and formed independently of the component comprising: providing a substrate; applying a paste with both metal particles and solder particles different from the metal particles onto at least one subregion of the substrate using a printing technique; and infiltrating the paste with solder in absence of the component, wherein the paste infiltrated with the solder forms a solder carrier layer. The solder infiltrating the paste is applied as at least one inherently rigid shaped part. A surface topography of the paste is modified by a stamp on the substrate.

### CROSS-REFERENCE TO RELATED APPLICATIONS

This application is a U.S. National Stage Application of International Application No. PCT/EP2019/053030 filed Feb. 7, 2019, which designates the United States of America, and claims priority to DE Application No. 10 2018 201 974.6 filed Feb. 8, 2018, the contents of which are hereby incorporated by reference in their entirety.

### TECHNICAL FIELD

The present disclosure relates to soldering. Various embodiments include methods for producing a structural unit which is to be soldered to at least one component by diffusion soldering and is formed independently of the component and/or methods for connecting a component to a substrate by means of diffusion soldering.

### BACKGROUND

In technical applications, for example in die attach, i.e. component fitting in semiconductor and/or microsystem technology, as well as in SMD (surface mount device) mounting, in which surface mounted components are mounted on printed circuit boards, but also in heat sink connection, reliable and in particular high temperature-stable solder connections are advantageous.

Soldering refers to a thermal method for the material-fit joining of materials, so that for example a component may be connected to a structural unit. In this case, respectively by means of a material present on a surface of the component and of the structural unit, as well as by a solder, a surface alloy is respectively produced, which connects the component to the structural unit via a solder layer formed by the solder, so that the material-fit connection is formed.

The respective workpiece, i.e. the component or the structural unit, is not melted to a particular depth during the soldering, but rather the aforementioned surface alloy is respectively formed on the workpiece. One possibility for producing the material-fit connection by means of soldering is so-called diffusion soldering, in which diffusion processes take place during the soldering operation, which can lead to extended formation of the solder connection. The solder layer may be formed from a solder carrier layer.

In die attach, SMD mounting, and heat sink connection and the like, in order particularly to save costs and to keep the environmental pollution particularly low, for example for employees, high-melting diffusion solder connections are sought in particular, which may be produced with commercially available lead-free solder pastes, in particular by the formation of intermetallic phases occurring particularly in the respective surface alloy and the solder. The intermetallic phase is a homogeneous chemical compound consisting of at least two metals, which exhibits a lattice structure, in which case one metallic component fraction predominates in the lattice and atomic or ionic bonds may additionally occur.

In the aforementioned applications, instead of diffusion soldering, a material-fit connection may, for example, be produced by silver sintering. In silver sintering, both the component and the structural unit, i.e. the respective so-called join partners, are connected in such a way that a significant pressure and temperature load acts on the respective join partner. A further disadvantage of silver sintering is the high material cost of silver.

Diffusion solder technologies may use particularly thin solder shaped parts in order to keep diffusion paths small. These techniques, however, require a particularly flat and clean surface on both the substrate, in particular the structural unit, and the component. The shortening of the diffusion paths is limited by properties relating to the handleability of the very thin solder shaped parts. Furthermore, the time required for the phase growth cannot be shortened arbitrarily. The phase growth may, or must, be continued further by thermal ageing after the production of the solder connection. In this case, the so-called thermal budgets of the component and of the substrate, which respectively represent a critical factor, need to be taken into account. In simple terms, the thermal budget may be understood as the heat which the component can absorb before it is, or becomes, impaired in its function, in particular its future function.

Furthermore, some methods may use separate copper pastes and solder pastes, in which copper particles are randomly distributed inside a join zone, between the join partners, so that effects detrimental to thermal reliability may possibly occur. Furthermore, this often requires a multiplicity of individual processes, or process steps, for producing the connection. This has a negative effect on introduction into serial production, or in a serial process.

It should, however, be possible to carry out serial production easily and efficiently with already existing manufacturing equipment, particularly for example in both die attach and SMD mounting. In addition, there is the risk of framework formation, which may already occur by isothermal solidification of intermetallic phases in a liquid during the soldering. In this case, at least some of the copper particles become connected to one another so that so-called closed chambers may be formed. In these chambers, both organic paste constituents, for example residues of a flux, and gases can no longer escape and remain inside the join zone, which may have a detrimental effect on the solder connection, in particular its mechanical and/or thermal stability.

DE 196 32 378 A1 describes a diffusion solder connection and a method for producing diffusion solder connections, distinguished in that a particularly diffusion-active, low-melting intermediate layer applied in a molten state is introduced in the form of a solder carrier between at least two connection partners. In this case, the solder carrier consists of a metal foil which is provided with solder layers on both sides, and the solder layers may themselves in turn be formed from a plurality of layers.

For bonding a package and a lid of a functional part, US 2010/0291399 A1 discloses the way in which a solder paste, which is formed by mixing a Cu-based metal powder with a solidus temperature of at least 400° C. and an Sn-based solder powder, is applied onto a lid of a difficult to solder material which was previously subjected to a coating having good solderability and heated, in order to obtain a solder layer.

DE 10 2015 200 991 A1 describes a method for producing a solder connection, in which two layers are applied onto a carrier element, wherein the first layer comprises at least metal particles and additives, in particular flux, and the second layer comprises at least solder, and wherein the carrier element and the two layers are subsequently subjected to a heat treatment in which the second layer is liquefied and enters into an active connection to the first layer.

### SUMMARY

The teachings of the present disclosure include methods by means of which components can be prepared for soldering and can be connected to one another particularly simply by soldering. For example, some embodiments include a method for producing a structural unit (10) which is to be soldered to at least one component by diffusion soldering and is formed independently of the component (38), comprising the steps:
i. providing a substrate (12) of the structural unit (10);
ii. applying a paste (16), which comprises at least metal particles (18) and solder particles (20) different to the metal particles (18), onto at least one subregion (22) of the substrate (12) by means of a printing technique; and
iii. infiltrating the paste (16) with solder (26) in the absence of the component (38), so that the paste (16) infiltrated with the solder (26) forms a solder carrier layer (14);
characterized in that the solder (26) is applied as at least one inherently rigid shaped part; and/or adaptation of the surface topography of the paste (16) is carried out by means of a stamp (32) on the substrate (12).

In some embodiments, the metal particles are formed from copper and/or iron and/or nickel and/or silver and/or gold.

In some embodiments, the paste (16) and/or the solder (26) and/or the solder carrier layer (14) are heat-treated before and/or after the infiltration.

In some embodiments, the solder (26) is applied before the infiltration onto at least one region of the paste (16) and/or onto at least one free part (30), which follows on from the subregion (22) and is free of the paste (16), of the substrate (12).

In some embodiments, stencil printing and/or screen printing is used as the printing technique.

In some embodiments, the substrate (12) is at least a part of a circuit board.

In some embodiments, tin plating (34) is applied at least onto a surface (36) of the solder carrier layer (14) that faces away from the substrate (12).

In some embodiments, the solder carrier layer (14) is subjected to at least one treatment, in particular a heat treatment, so that propagation of at least one intermetallic phase (28) in the solder carrier layer (14) is promoted.

In some embodiments, at least some of the metal particles (18) of the paste (16) respectively comprise at least one functional coating (42, 44, 46).

As another example, some embodiments include a method for connecting a component (38) to a substrate (12) by means of diffusion soldering, comprising the steps:
i. providing a structural unit (10) which comprises the substrate (12) and a solid solder carrier layer (14), which is held on the substrate (12) independently of the component (38) and comprises a paste (16) infiltrated with solder (26);
ii. bringing at least one region (40) to be soldered of the component (38) in contact with the solder carrier layer (14); and
iii. soldering the substrate (12) to the component (38) via the solder carrier layer (14) by means of diffusion soldering, during which the solder carrier layer (14) is at least partially melted;
characterized in that the component (10) is produced by means of a method as described herein.

In some embodiments, the component (10) is a surface mounted component.

### BRIEF DESCRIPTION OF THE DRAWINGS

Various embodiments of the teachings herein are explained in detail below with the aid of schematic drawings, in which:

FIG. 1 shows a sequence of a method incorporating teachings of the present disclosure for producing a structural unit, with the aid of schematic representations of method steps;

FIG. 2 shows a schematic representation of an adaptation of the surface topography of a paste, as a further step;

FIG. 3 shows a schematic representation of tin plating of a solder carrier layer;

FIG. 4 shows a sequence of a method incorporating teachings of the present disclosure for connecting a component to a substrate by means of diffusion soldering, with the aid of schematic representations of method steps;

FIG. 5 shows a schematic representation of a metal particle of the paste, which comprises a coating; and

FIG. 6 shows a schematic plan view of a large-format substrate formed as at least one circuit board.

### DETAILED DESCRIPTION

Some embodiments include a method for producing a structural unit which is to be soldered to at least one component by diffusion soldering and is formed independently of the component. In a first step, a substrate of the structural unit is provided. In this case, the substrate is intended to mean a part to be treated of the structural unit, in particular a surface which is formed from a material and is subsequently provided at least partially with solder, or a solder carrier layer, so that the component can be connected to the structural unit by means of soldering. Briefly stated, the substrate is one of the surfaces of the structural unit, on which a solder connection to a component independent of the structural unit is subsequently intended to be formed. In a second step, a paste, which comprises at least metal particles and solder particles different to the metal particles, is applied onto at least one subregion of the substrate by means of a printing technique. The feature that the solder particles are particles different to the metal particles means that the metal particles and the solder particles are at least partially formed from different materials. The metal particles may, for example, be formed from an elemental metal or a metal alloy.

The paste applied onto the substrate furthermore comprises cavities, which may be located between the respective metal particles and the respective solder particles, and between metal particles and solder particles. In a third step, the paste is infiltrated with solder in the absence of the component, so that the paste infiltrated with the solder forms a solder carrier layer, in particular on the substrate of the structural unit. This means that the infiltration of the paste with the solder is carried out independently of, or separately from, the component, that is to say without the component being connected to the structural unit. In other words, during the infiltration of the paste with the solder, connection or soldering of the component to the structural unit does not take place. The solder may, for example, be a solder containing tin or a solder formed on the basis of tin. It is furthermore possible for the solder to be pure tin. The solder particles of the paste may likewise contain tin or be formed from pure tin.

In the third step, the paste is therefore infiltrated with the solder, while connection of the component to the structural unit does not take place. The structural unit is therefore produced separately from, or independently of, the component, so that the substrate is provided independently of, or separately from, the component with the paste and the solder. The solder carrier layer may form a material-fit connection, in particular a solder connection, between the component and the structural unit during subsequent soldering, not belonging to the method, of the structural unit to the component. The structural unit, which now comprises the solder carrier layer, is subsequently a kind of semifinished product, which already comprises the substrate to be soldered and therefore to be connected to the component, and the connecting device which is held on the substrate and comprises the solder and the paste, and is preferably inherently rigid and dry, i.e. the solder carrier layer, by means of which the substrate can be connected to the component. With the structural unit produced, a solder connection may be formed, or produced, particularly in such a way that the connecting device is at least partially heated and thereby melted in order finally to solder, and therefore connect with a material fit, the component to the substrate.

In some embodiments, the solder is applied as at least one inherently rigid shaped part, and/or adaptation of the surface topography of the paste on the substrate is carried out by means of a stamp, particularly in an additional method step. In this way, the solder may be applied according to the shape of the solder carrier layer, or connecting device, to be formed, so that the subsequent infiltration may likewise be carried out simply. The step of adapting the surface topography is carried out before the third step.

During the adaptation of the surface topography, a particularly flat and therefore in particular uniform and planar shape is imparted to the surface of the paste facing away from the substrate, this shape in particular being arranged parallel to the surface of the substrate and therefore of the structural unit. In this way, during a soldering process subsequent to the method, a particularly good solder connection may be formed between the component and the structural unit. If, for example, the component is not planar on the side on which it can be soldered to the solder carrier layer, but comprises a three-dimensional structure, this may be incorporated during the adaptation of the surface topography, for example into the solder carrier layer, so that the component may for example be placed with a particularly accurate fit on the solder carrier layer.

In some embodiments, the first step to the third step are carried out in a chronologically adapted order. The first step, the provision of the substrate, is carried out before the second step, the application of the paste. The second step is in turn carried out chronologically before the third step, the infiltration of the paste with the solder.

Such embodiments infiltrate the paste with solder on the substrate without fitting with the component having to take place. The structural unit thus provided, which has the substrate that comprises the solder carrier layer or is connected thereto, and which after the third method step is equivalent to a semifinished product, may be used simply in existing production systems for electronics without carrying out a modification of the production system or a diffusion soldering process that takes place therein. In this way, particularly high investment costs and/or particularly elaborate refitting, particularly on the production system or the manufacturing line, may be obviated, particularly in series manufacturing.

In contrast thereto, in the case of previous diffusion soldering, the solder carrier layer, which allows subsequent contacting of the component, is connected directly to the component during its generation, or production, that is to say during the infiltration. This leads in particular to negative repercussions on series manufacturing, since process sequences to be complied with are made more difficult. Furthermore, flux or comparable materials possibly present in the solder and/or the paste can only escape from the solder carrier layer with difficulty because of the component applied onto the solder carrier layer.

In some embodiments, efficient production of a substrate prepared for the diffusion soldering, or of a structural unit that comprises a solder carrier layer, is made possible by means of the methods herein. Furthermore, some embodiments include a method for producing a reliable, high temperature-stable and high-melting diffusion solder connection. In this case, commercially available, in particular lead-free, solders may be used in the method, and a soldering process carried out on the structural unit may be carried out in a conventional manufacturing line, in particular without retrofitting.

For soldering optionally carried out at the end of the method, the connecting device produced, or the solder carrier layer, is now configured in such a way that, in particular, it has a certain residual reactivity on its surface, in particular of the solder, which may be used for subsequent component contacting.

Furthermore, the absence of the component during the infiltration of the paste allows the infiltration to take place substantially or reliably. In some embodiments, a defect content between the metal particles and one another or with respect to one another may be reduced. The metal particles may cause one another to be aligned in their crystal structure, or to be oriented in their crystal structure. Owing to the absence of the component, the metal particles in the solder, or in the solder carrier layer, may be arranged particularly flexibly so that, inter alia, fewer defects can occur.

Holes, or so-called voids, in the solder carrier layer may also be reduced in size, or their occurrence may be reduced, by keeping the component separate. In some embodiments, during the infiltration without a component, the solder can penetrate into the paste at least as efficiently, in particular by means of diffusion and/or capillary effects, as with a component applied. Furthermore, particularly simple degassing, in particular of organic elements or compounds, for example from a flux contained in the solder, is possible. This is because the elements or compounds can escape through the non-enclosed or uncovered surface of the paste-solder mixture, and therefore of the solder carrier layer which is formed has or been formed thereby.

This effect may, for example, be further enhanced by the infiltration and/or a subsequent diffusion soldering process being carried out for example with exclusion of air, particularly in a vacuum. Briefly stated, preconditioning, that is to say preparation, of a solder carrier layer, used directly for the diffusion soldering, of the structural unit may therefore be carried out, in which case the structural unit is for example formed as a circuit board. By the preconditioning, efficient diffusion soldering may be carried out by means of the existing manufacturing line, or manufacturing equipment.

In some embodiments, the metal particles are formed from copper and/or iron and/or nickel and/or silver and/or gold. This means that at least one material of one of the metal particles comprises copper and/or iron and/or nickel and/or silver and/or gold. The aforementioned metals may respectively form one of the metal particles in their respective elemental form. Thus, in the paste, some of the metal particles may be formed from one of the metals mentioned and others of the metal particles may be formed from another of the metals mentioned. In some embodiments, a single one of the metal particles may be formed from one or more of the materials mentioned, or from another metal, or a material comprising at least one of the metals or a metal compound. For example, depending on the mechanical stability required for the solder carrier layer, at least one of the metals mentioned may be used for forming the metal particles and, at the same time, material costs may for example be kept particularly low.

In some embodiments, the paste and/or the solder and/or the solder carrier layer are heat-treated before and/or after the infiltration. In this way, for example, it is possible to achieve particularly good storability of, in particular, so-called large-format substrates which comprise a plurality of structural units with respective substrates. This may, for example, comprise drying of the paste, in particular by increasing an ambient temperature, which takes place after the printing. This means that the paste becomes less viscous during the heat treatment, for example because materials which make the printing of the paste onto the substrate particularly easy may additionally be contained in the paste, wherein these materials can escape from the paste.

In some embodiments, the solder is applied before the infiltration, in particular after the second step, onto at least one region of the paste. In some embodiments, the solder is applied before the infiltration, after the second step, onto at least one free part, which follows on from the subregion and is free of the paste, of the substrate. In this case, the free part of the substrate is located at least partially in direct proximity to the subregion on which the paste is applied on the substrate. This means that the part that is free of the paste is a region of the substrate on which the paste is not applied. In other words, application of solder is carried out onto at least one part of the paste and/or onto at least one part of the substrate, which is at least partially in direct proximity to the subregion. By the application, infiltration of the paste with the solder may be carried out.

In some embodiments, stencil printing and/or screen printing is used as the printing technique for applying the paste. In other words, the paste is placed onto at least one subregion of the substrate by means of stencil printing and/or screen printing. Both stencil printing and screen printing have the advantage for the application of the paste that the paste, or a paste depot, can be applied or placed on the substrate in a particularly flat fashion. The planarity, in particular during the diffusion soldering, allows suitable formation of, for example, a solder clearance, in order to obtain a particularly high quality of the solder connection. For use of the residual activity or reactivity of the remaining solder, on a surface or upper side of the infiltrated paste, which solder is formed at least from the solder, the solder particles and the metal particles, during subsequent soldering, in particular diffusion soldering, the solder clearance when bringing the component in contact has a particularly small height, so that intermetallic phases can grow through as far as the component within a conventional solder profile.

In some embodiments, the adaptation of the surface topography is carried out by means of a nonadhesive stamp. In this case, the stamp, or in particular its embossing face, may be formed from polytetrafluoroethylene, which reacts with particularly low adhesion with the surface to be adapted of the applied paste. In this way, for example, smoothing of the surface is possible in a particularly advantageous and efficient way.

In some embodiments, the substrate is at least a part of a circuit board. The circuit board may be used as a mechanical carrier, in particular for the wiring of the line structures with the component, in particular electronic component. With the circuit board, diffusion soldering subsequent to the method may be carried out particularly efficiently, in particular by means of the existing manufacturing line.

In some embodiments, tin plating is applied at least onto a surface of the solder carrier layer that faces away from the substrate. In this case, the surface may in particular be, or coincide with, the aforementioned surface through which the organic elements can escape. In addition, the surface is at least partially a face of the solder carrier layer, which can be connected to the component during the diffusion soldering following the method. The tin plating may in particular comprise or contain so-called “chemical tin”, which in general may particularly advantageously form a planar, solderable metallic surface.

By the application of the tin plating onto the solder carrier layer, for example, an increase in the amount of solder available in the solder carrier layer may be provided in a simple way for the subsequent joining of the structural unit to the component, which may also respectively be referred to as join partners.

In some embodiments, the tin plating, that is to say the application of the tin, in particular chemical tin, may be carried out on the join partner other than the structural unit, in particular the component. This means that tin is applied not on the solder carrier layer of the structural unit, but on the component. In particular, the application of the tin plating serves to provide a thin solderable layer, in particular on the solder carrier. To this end, as an alternative to tin plating, in particular chemical tin plating, it is also possible to carry out galvanic deposition. In particular, the tin plating and/or the galvanic deposition may be used when the solder carrier layer has for example been dried by heat-treating for a particularly long time and/or intensively, and/or has been heat-treated in an additional method step or before the method or after the third step of the method.

In some embodiments, the solder carrier layer is subjected to at least one treatment, in particular a heat treatment, so that propagation of at least one intermetallic phase in the solder carrier layer is promoted. The treatment may for example take place, or be carried out, particularly in the third step of the method and/or thereafter, in order to force formation, or growth, of intermetallic phases in the mixture of solder particles and metal particles in the paste. If particularly extensive conversion into, or formation of, the intermetallic phases takes place, an advantage may be obtained. This is particularly low volume shrinkage inside a join zone between the join partners, in particular during subsequent operation of the module, that is to say of the component soldered together with the structural unit. Nevertheless, premature solder conversion, or formation of the intermetallic phases, may lead to a loss of a compensating effect of the solder carrier layer during the joining process.

In some embodiments, at least some of the metal particles of the paste respectively comprise at least one functional coating. The coating and the metal particles, which may respectively in particular be formed as small copper spheres, are at least partially formed from different materials to one another.

Furthermore, the coating is not the solder and not the solder particles. These are likewise respectively formed from at least one material which may be different for the solder in comparison with the solder particles. The functional coating may undertake at least one function, and in particular is respectively applied onto one of the metal particles.

Thus, the coating may delay the formation of the intermetallic phase on the metal particles. In this case, the delay may take place in particular during steps 1 to 3, in particular during the second step of the method. A plurality of functional layers may be provided, so that a respective metal particle may comprise a plurality of successive coatings, which in particular are different to one another. Thus, the coatings may for example have a sequence in which a layer, or coating, that promotes wetting is followed by a layer that inhibits wetting. As an alternative or in addition, a layer that promotes wetting may follow a layer that inhibits wetting, and vice versa, or an arbitrary sequence of the coating respectively forming a layer, in particular a functional coating, is possible.

In this case, the coating that inhibits wetting has the property that the respective metal particle cannot be wetted particularly well, for example with the solder, because of the coating, but in the case of the coating that promotes wetting the converse may be the case. The advantage of the functional coating is, for example, maintaining mobility of the metal particles and/or of a residual fraction of molten regions in the join zone during the diffusion soldering, for example in order to be able to ensure the compensating effect, or a certain minimum extent of the compensating effect, during the joining process. Thus, by a coating that inhibits wetting, which in particular is metallurgically inactive, slight rearrangement of the metal particles, or a high mobility of the metal particles in the solder surrounding them, or in the solder particles, may take place, so that for example the lattice structure is formed particularly advantageously.

Some embodiments include a method for connecting a component to a substrate by means of diffusion soldering. The method in this case may comprise the following steps: in a first step, a structural unit is provided, which comprises the substrate and a solid solder carrier layer, which is held on the substrate independently of the component and comprises a paste infiltrated with solder. In other words, in a state separated from the component, that is to say without the substrate being connected to the component, the structural unit comprises the solder carrier layer.

In a second step of the method, at least one region to be soldered of the component is brought in contact with the solder carrier layer. In a third step of the method, soldering the substrate to the component via the solder carrier layer is carried out by means of diffusion soldering, during which the solder carrier layer is at least partially melted. In this case, the soldering process of the diffusion soldering is initiated in particular by, or via, activation. The activation may this case be carried out in different ways. For example, the activation may be carried out by a gas and/or by adding a flux, a so-called additive flux. During activation by a gas, the structural unit and the component are introduced into a reducing atmosphere, which may for example comprise formic acid. In this way, on metal surfaces, in particular of the solder carrier layer and/or of the component, metal compounds which may have been formed there, in particular by oxidation, can be reduced back to a pure metal, so that the soldering may start particularly advantageously and the finished solder connection has a particularly high quality. The soldering process itself may be carried out in the standard manufacturing line. During the soldering, after melting or at least partial melting of the solder, in particular by diffusion processes but also by capillary processes, formation takes place of a contact layer which in particular is particularly thermally stable because of the random distribution of the metal particles in the solder carrier layer. This is formed in particular by solidification of the solder subsequent to the melting.

In some embodiments, the structural unit is produced by means of a method as described herein. In some embodiments, the component is a surface mounted component. A surface mounted component is referred to as a surface mount device (SMD). In contrast to components of so-called pin-in-hole mounting, these components provide that a printed circuit board carrying them, which for example is the structural unit, may be soldered compactly.

In some embodiments, the method preconditions a structural unit 10 for possible subsequent, in particular efficient, diffusion soldering, particularly in conventional manufacturing lines comprising existing manufacturing equipment. By these methods, the production of a reliable, high temperature-stable or high-melting diffusion solder connection may be made possible. In other words, the method is used for the efficient production of a substrate 12 prepared for diffusion soldering, or of a structural unit 10. In this case, the method for the efficient production of the substrate 12 prepared for diffusion soldering, or of the structural unit 10, comprises a plurality of steps:

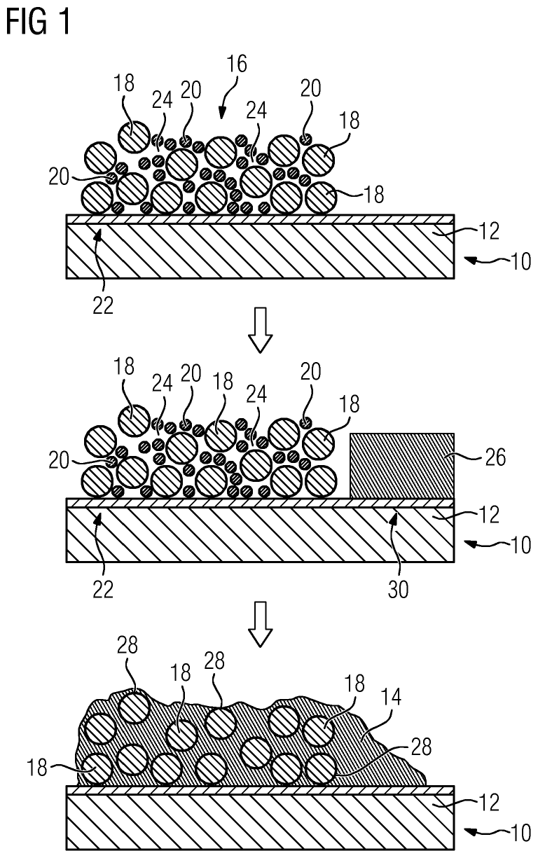

In a first step i., the substrate 12 of the structural unit 10 is provided. In this case, the substrate 12 is at least one subregion of the structural unit 10, which in particular is treatable so that a solder carrier layer 14 can be formed on at least the subregion of the substrate 12 by the method. In FIG. 1, successive steps are partially separated by an arrow, the direction of the arrow indicating the chronological order of the steps of the method, the so-called method steps. In this case, the result of a second step ii. of the method is already shown in the first schematic representation, which is the top representation of FIG. 1. This means that the first method step i., the provision of the substrate 12, has likewise already taken place in the top representation of FIG. 1.

In a second step ii., a paste 16, which comprises at least metal particles 18 and solder particles 20 different to the metal particles 18, is applied on at least one subregion 22 of the substrate 12 by means of a printing technique. In this case, the metal particles 18 differ from the solder particles 20 particularly in that they are different particle types, respectively formed from different materials. The metal particles 18 may, for example, be formed from copper and/or iron and/or nickel and/or silver and/or gold. Furthermore, the paste 16 applied onto the subregion 22 in the second step ii. comprises cavities 24.

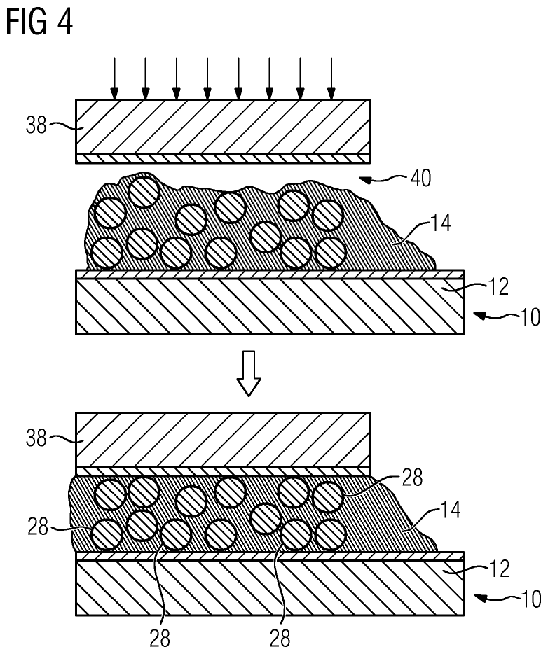

In a third step iii. of the method, the start of which is shown in the central representation FIG. 1 and the result of which is shown in the bottom representation FIG. 1, the paste 16 is infiltrated with solder 26 in the absence of the component, so that the paste 16 infiltrated with the solder 26 forms the solder carrier layer 14. Absence of the component, which is shown FIG. 4, means that there is no connection between the component and the structural unit 10, in particular by means of the solder carrier layer 14.

This means that in the proposed method, the component is not soldered to the structural unit 10, in particular by means of diffusion soldering. The method is used to form, or provide, the solder carrier layer 14, so that for example soldering, which is proposed later in the second method, is possible in the existing manufacturing, particularly in the existing manufacturing system. The introduction, or infiltration, of the solder 26 into the paste 16 is in this case carried out in a similar way to the diffusion soldering.

This means that the solder 26 penetrates particularly well into the paste 16, in particular because of diffusion processes, and capillary processes that possibly furthermore take place. This may, for example, be carried out by adding, or radiating, heat onto the substrate 12 and/or the paste 16. During the infiltration, in particular by the metal particles 18 and the solder particles 20, but possibly also by some of the solder 26, intermetallic phases 28 are formed, the growth of which may in particular begin at a respective surface of a respective metal particle 18. The material of the solder particles 20 may be different to the material of the solder 26. Thus, for example, one of the materials may additionally contain a flux, or a first type of flux, while the other material contains another type of flux, or the like.

Furthermore, during the formation of the solder carrier layer 14, the solder 26 penetrates particularly into the cavities 24, which the paste 16 comprises at least until the third method step iii. The bottom representation in FIG. 1 shows the finished solder carrier layer 14 on the substrate 12 of the structural unit 10. In this case, the substrate 12 is now particularly advantageously prepared for diffusion soldering that takes place later. The substrate 12 provided here, or the component formed with the solder carrier layer 14, is equivalent to a so-called semifinished product and may be used for subsequent diffusion soldering in the existing manufacturing line, or an existing production system, in particular for electronics and in particular without modification. In this way, for example, it is possible to save on elaborate refitting and therefore costs.

The paste 16 and/or the solder 26 and/or the solder carrier layer 14 may be heat-treated before and/or after the infiltration. By the heat treatment, for example, drying may be achieved. By the drying, the paste 16 becomes for example more geometrically stable, so that a subsequent further treatment, in particular by a third method step iii, may be carried out on the at least one subregion 22 intended therefor.

In some embodiments, the solder 26, or the solder carrier layer 14, may be dried after the infiltration carried out in the third step iii. In this way, for example, easy handleability of the respective structural unit 10 may be achieved for further processing subsequent to the method.

As in the central representation of FIG. 1, the solder may be applied, in particular after the second step ii., or in particular before the infiltration in the third step iii. of the method onto at least one part 30, which follows on from the subregion 22 and is free of the paste 16, of the substrate 12. In some embodiments, the solder 26 may be applied onto at least one region of the paste before the infiltration, after the second step ii, or in particular after the third step iii.

Because of the infiltration of the paste 16 in the absence of the component 10, the infiltration and therefore the production of the solder carrier layer 14 take place substantially more reliably. Furthermore, a defect content between the metal particles 18 is significantly reduced, that is to say fewer so-called holes or voids are formed. Furthermore, lattice defects, or defects of a lattice formed at least partially by rearrangement of the metal particles 18 with respect to one another, may likewise be reduced by the method.

In some embodiments, organic constituents, for example of the solder particles 20 and/or of the solder 26, can escape, in particular as a gas, from the solder carrier layer 14 formed from the paste 16 and the solder 26. During subsequent joining by diffusion soldering of the structural unit 10, for example to the component, a smaller organic fraction therefore remains inside a join zone, which is formed in particular by the solder carrier layer 14. In this way, a solder connection may be produced by means of the solder carrier layer 14. Furthermore, in contrast to conventional diffusion soldering, fewer chambers, in particular closed chambers, are formed during the, in particular, isothermal solidification of the intermetallic phases, during which metal particles 18 are connected to one another.

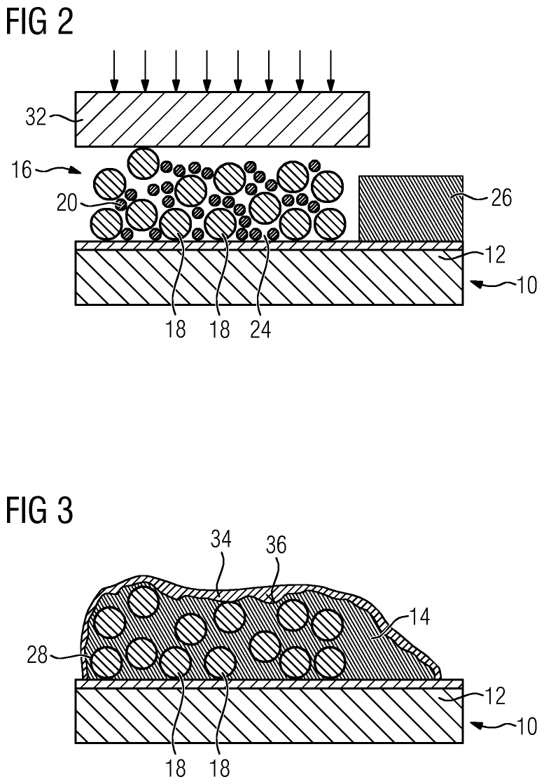

FIG. 2 shows a schematic representation of adaptation of the surface topography of the paste 16 as a further, in particular optional, step of the method. In the exemplary embodiment shown, the adaptation of the surface topography is planarization. In some embodiments, the planarization of the paste 16 on the substrate 12 takes place before the third step iii. and after the second step ii. By the planarization, which already takes place at least partially because of the printing, planarity of the solder carrier layer 14 may be achieved. This may be done by means of an, in particular, nonadhesive stamp 32 which is pressed onto the paste 16, in particular plane-parallel to the substrate 12. In this case, an embossing face of the stamp 32 may be formed from polytetrafluoroethylene. By means of the planarization, or adaptation of the surface topography, a solder clearance in a subsequent soldering method, for example the one proposed in FIG. 4, may have a particularly small height, so that for example the intermetallic phases can grow through to the component.

FIG. 3 shows a schematic representation of a tin plating 34. In some embodiments, the application of the tin plating 34, at least on a surface 36 of the solder carrier layer 14 facing away from the substrate 12, takes place in an, in particular, further optional step of the method. In general, in the proposed method, the remaining solder 26, or at least some of the solder 26, which in particular forms the surface 36 of the solder carrier layer 14, is used for subsequent component contacting. By the tin plating 34, which may in particular be formed from so-called “chemical tin”, the amount of solder available may be increased so that the component contacting can be carried out. Furthermore, the reactivity, in particular a remaining residual reactivity, or surface reactivity, may be influenced. In this way, for example a soldering process may be initiated particularly simply during subsequent diffusion soldering.

In some embodiments, as an alternative or in addition to the application of the tin plating 34, the structural unit 10 and the solder carrier layer 14 applied onto it may be subjected to a treatment, in particular a heat treatment. During this treatment, propagation of at least one intermetallic phase 28 in the solder carrier layer 14 may be promoted. As an alternative, instead of the tin plating 34, for example galvanic deposition may be carried out on the surface 36. Both tin plating 34 and galvanic deposition serve as a measure to provide an, in particular, solderable layer, in particular on the surface 36. For example, by means of an, in particular, long and/or hot heat pretreatment, extensive formation of intermetallic phases 28 may be achieved.

Nevertheless, the treatment, in particular the heat treatment, may entail substantial loss of a compensating effect of the layer in the joining process, for example since mobility of the metal particles 18 is reduced. The tin plating 34 may compensate somewhat for this effect. Furthermore, the effect may be at least partially counteracted with coated metal particles 18, such as one which is shown by way of example in FIG. 5. Details of this in the description relating to FIG. 5.

On the other hand, extensive formation of intermetallic phases 28, even before the actual diffusion soldering, may already have a effect on the subsequent soldering process. The treatment and the associated increased conversion into intermetallic phases 28, in particular already before or during the provision of the solder carrier layer 14, in particular during subsequent operation of a module which is formed from the structural unit 10 and the component shown below, with the joining zone particularly low volume shrinkage may take place, or occurs.

FIG. 4 shows a sequence of a second method. This second method is used to connect a component 38 to the substrate 12, in particular to the structural unit 10, by means of diffusion soldering. The method proposed in FIG. 4 will often be referred to in the rest of the text as the second method, in particular when a difference from the first method, proposed in FIG. 1, is intended to be illustrated. In this case, the second method comprises a plurality of steps. In a first step i. of the method for connecting the component 38, the structural unit 10 is provided. In this case, the structural unit 10 comprises the substrate 12 and a solid solder carrier layer 14, which is held on the substrate 12 independently of the component 38. The solder carrier layer 14 in this case comprises a paste 16 infiltrated with solder 26, or the solder carrier layer 14 may be formed at least partially from this paste 16. This means that the substrate 12 already comprises the solder carrier layer 14 in a state separated from the component 38. In other words, the solder carrier layer 14 is already bonded to the substrate 12 before the solder carrier layer 14 is connected to the component 38 during the second method.

In some embodiments, the structural unit 10 is produced by means of the first method, proposed in FIG. 1, or according to a method having the additional steps as represented in FIG. 2 and FIG. 3. In a second step ii. of the second method, at least one region 40 to be soldered of the component 38 is brought in contact with the solder carrier layer 14. This is shown by the upper representation of FIG. 4, in which the component 38 is brought, or is, in contact particularly with a surface of the region 40. In a third and last step of the method, the substrate 12 is soldered to the component 38 via the solder carrier layer 14 by means of diffusion soldering, during which the solder carrier layer 14 is at least partially melted.

This finished soldered state is shown in the lower representation of FIG. 4. By the soldering process of the diffusion soldering, the intermetallic phases, as may be seen in FIG. 4, are formed further, in which case, for example, a particularly high thermal conductivity of the solder connection may in particular be formed. In some embodiments, the component 38 is a surface mounted component, such as is used for example in surface mounting, in contrast to pin-in-hole mounting, so that, for example, particularly flat modules consisting of the component 38 and the structural unit 10 may be formed.

FIG. 5 shows a schematic representation of a metal particle 18 of the paste 16 which comprises a coating. In some embodiments, metal particles 18 which constitute at least some of the metal particles 18 of the paste 16, and which respectively comprise at least one functional coating 42, may be used for the first method as well as the second method, but in particular during the first method. In this case, for example, the outer-lying layer 44 may be a coating that inhibits or delays the formation of the intermetallic phases 28 on the metal particles 18. In this way, for example, mobility of the metal particles 18 in the molten solder of the solder particles 20, or in the solder 26, may be maintained, so that for example particularly advantageous, at least partial lattice arrangement of the metal particles 18 may take place. By a further layer or the layer 44, the mobility may for example be maintained in the joining process as well.

In contrast to the layer 44 that inhibits wetting, a second layer 46 may be formed as a layer that promotes wetting. An almost arbitrary sequence of layers 44 and 46 that inhibit wetting and promote wetting may be envisioned. In this case, a metallurgically inactive layer, which for example allows slight mobility of the metal particles 18 in the solder 26, may be used, in particular as the second layer 46 or second coating. On the other hand, the more wettable or wetting layer may facilitate redistribution. For example, the compensating effect during the joining process, which is characterized by the method shown in FIG. 4, may be ensured by the functional coating 42. In this case, the coating and the metal particles 18 are respectively formed from different materials to one another, that is to say the coating is not the solder 26 and also not the solder particles 20, but a material different to these materials.

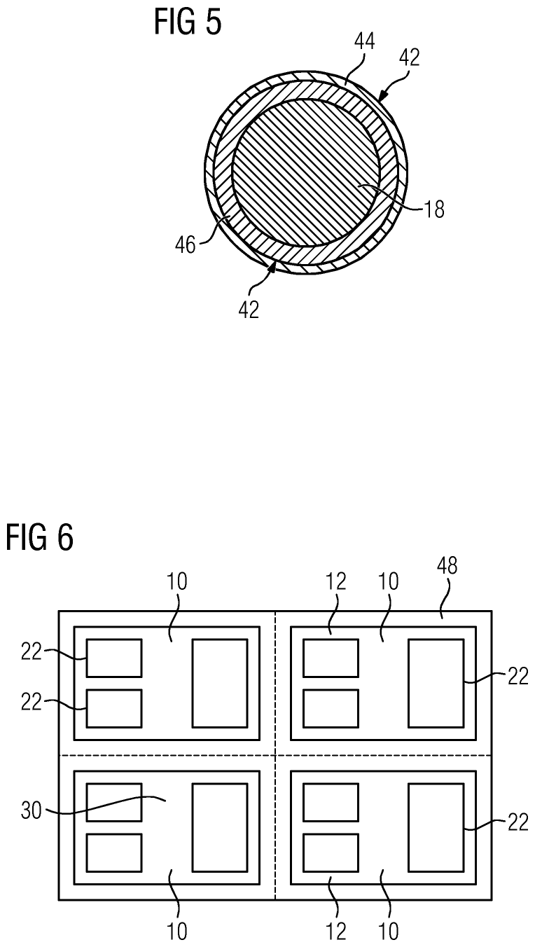

FIG. 6 shows a schematic plan view of a large-format substrate 48 formed as at least a circuit board. The respective structural unit 10 with respective subregions 22 may be seen particularly well on the large-format substrate 48. In some embodiments, the respective subregion 22 of the structural unit 10 may be produced in particular in its shape by using a printing technique in the second method step ii. of the first method. Suitable printing techniques are, in particular, stencil printing and/or screen printing, by means of which the subregion 22 which is delimited in particular from the solder-free, or paste-free, part 30 of the substrate 12. In some embodiments, the substrate 12, or the structural unit 10 comprising the substrate 12, is the circuit board already mentioned in the introduction, which may be used as a carrier during wiring or for the component 38 to be connected by soldering.

What is claimed is:

1. A method for producing a structural unit to be soldered to a component by diffusion soldering and formed independently of the component, the method comprising:
providing a substrate;
applying a paste with both metal particles and solder particles different from the metal particles onto at least one subregion of the substrate using a printing technique; and
infiltrating the paste with solder in absence of the component, wherein the paste infiltrated with the solder forms a solder carrier layer;
wherein the solder infiltrating the paste is applied as at least one inherently rigid shaped part; and
a surface topography of the paste is modified by a stamp on the substrate.

2. The method as claimed in claim 1, wherein the metal particles comprise at least one element selected from the group consisting of: copper, iron, nickel, silver, and gold.

3. The method as claimed in claim 1, wherein the paste and/or the solder and/or are heat-treated before and/or after the infiltration.

4. The method as claimed in claim 1, further comprising applying the solder before the infiltration onto at least one region of the paste and/or onto at least one free part, which follows on from the subregion and is free of the paste, of the substrate.

5. The method as claimed in claim 1, wherein the printing technique includes stencil printing and/or screen printing.

6. The method as claimed in claim 1, wherein the substrate comprises at least a part of a circuit board.

7. The method as claimed in claim 1, further comprising applying tin plating to at least a surface of the solder carrier layer facing away from the substrate.

8. The method as claimed in claim 1, further comprising subjecting the solder carrier layer to a heat treatment, promoting propagation of at least one intermetallic phase in the solder carrier layer.

9. The method as claimed in claim 1, wherein at least some of the metal particles of the paste comprise a functional coating.

10. A method for manufacturing a system comprising a component to a substrate by means of diffusion soldering, the method comprising:
providing a structural unit including the substrate and a solid solder carrier layer held on the substrate independently of the component and including a paste infiltrated with solder;
bringing at least one region to be soldered of the component in contact with the solder carrier layer;
soldering the substrate to the component via the solder carrier layer using diffusion soldering, during which the solder carrier layer is at least partially melted;
after producing the component by:
providing a substrate;
applying a paste with both metal particles and solder particles different from the metal particles onto at least one subregion of the substrate using a printing technique; and
infiltrating the paste with solder in absence of the component, wherein the paste infiltrated with the solder forms a solder carrier layer;
wherein the solder infiltrating the paste is applied as at least one inherently rigid shaped part; and
a surface topography of the paste is modified by a stamp on the substrate.

11. The method as claimed in claim 10, wherein the component comprises a surface mounted component.
